(19) United States
(12) Patent Application Publication
(10) Pub. No.: US 2026/0309808 A1
(43) Pub. Date: Oct. 8, 2026

(54) ONLINE MONITORING METHOD AND SYSTEM FOR OPERATING STATE OF SECONDARY CURRENT CIRCUIT NEUTRAL LINE

(71) Applicants: YUNNAN POWER GRID CO., LTD, Kunming (CN); YUNNAN ELECTRIC POWER TEST AND RESEARCH INSTITUTE (GROUP) CO., LTD, Kunming (CN)

(72) Inventors: Yuanhang YANG, Kunming (CN); Jing CHEN, Kunming (CN); Qiaowei YANG, Kunming (CN); Yinyin LI, Kunming (CN); Jiong CHEN, Kunming (CN); Kao ZHOU, Kunming (CN); Xiao ZHANG, Kunming (CN); Hengchu SHI, Kunming (CN); Hao YOU, Kunming (CN); Benyu LI, Kunming (CN); Yigong XIE, Kunming (CN); Shuying PANG, Kunming (CN); Minghui ZHAO, Kunming (CN); Min ZHANG, Kunming (CN); Shanke HUANG, Kunming (CN); Gang CHEN, Kunming (CN); Rui ZHANG, Kunming (CN); Jiarun DONG, Kunming (CN); Yurong LEI, Kunming (CN); Jianyu ZHOU, Kunming (CN); Yunkang XIONG, Kunming (CN); Fei YANG, Kunming (CN); Zhongjun LU, Kunming (CN); Hui JIN, Kunming (CN); Zicheng WANG, Kunming (CN); Wenjie GUO, Kunming (CN); Jinquan XIAO, Kunming (CN); Qi ZHANG, Kunming (CN)

(73) Assignees: YUNNAN POWER GRID CO., LTD, Kunming (CN); YUNNAN ELECTRIC POWER TEST AND RESEARCH INSTITUTE (GROUP) CO., LTD, Kunming (CN)

(21) Appl. No.: 19/682,883

(22) Filed: May 20, 2026

Related U.S. Application Data
(63) Continuation of application No. PCT/CN2024/107214, filed on Jul. 24, 2024.

(30) Foreign Application Priority Data
Nov. 21, 2023 (CN) 202311550444.8

(51) Int. Cl. G01R 31/72; G01R 31/54

(52) U.S. Cl. CPC G01R 31/72; G01R 31/54

(57) ABSTRACT

An online monitoring method for an operating state of a secondary current circuit neutral line includes: collecting neutral line current by a high-precision sensor and processing the neutral line current to obtain fundamental components of secondary currents of each of neutral lines in a substation free from influences of harmonics and transients, and uploading the fundamental components to a protection information master station; retrieving information from an original configuration connected to the protection information master station to acquire three-phase secondary current circuit information of each bay in the substation, summarizing secondary current information of all monitoring ranges, and performing grouping and classification marking by substation, bay and winding; and conducting operation and analysis through collected information, automatically identifying and confirming an operating state of a line first, and calculating a linearity of outlier deviation and continuous dynamic trend deviation degree of each winding in each bay.

### CROSS-REFERENCE TO RELATED APPLICATIONS

The present application is a continuation application of International Application No. PCT/CN2024/107214, filed on Jul. 24, 2024, which claims priority to Chinese Patent Application No. 202311550444.8, filed on Nov. 21, 2023. The disclosures of the above-mentioned applications are incorporated herein by reference in their entireties.

### TECHNICAL FIELD

The present application relates to the technical field of online monitoring, and in particular to an online monitoring method and a system for an operating state of a secondary current circuit neutral line.

### BACKGROUND

In power system stations, secondary equipment performs functions such as monitoring, control and protection on the operating state of primary equipment. As the analog input of secondary equipment, secondary current is critical for accuracy and reliability. A secondary current circuit involves current transformers, local control cabinets, outdoor cables, wiring terminals of secondary equipment and collection circuits, which have complex wirings, numerous links and concealed defects. Existing secondary equipment has no determination logic for neutral line open circuit. When a ground fault occurs in a power system, the current transformer will experience increased excitation current and saturation due to loose connection or open circuit of the neutral line in the secondary circuit, further causing loss of selectivity of relay protection equipment, which may lead to serious consequences such as maloperation for out-of-zone faults or refusal to operate for in-zone faults. Therefore, it is necessary to monitor and determine neutral line open circuit, reveal hidden dangers of neutral line open circuit in secondary current circuits in advance, and ensure safe and stable operation of the power grid.

At present, certain researches and applications have been conducted on monitoring methods for loose connection or open circuit of neutral lines in current secondary circuits, which are mainly divided into the following categories:

The first is the harmonic analysis method. When the neutral line of a current secondary circuit is open, the harmonic components in the current circuit change. Monitoring the characteristics of high-order harmonics can sensitively determine neutral line open circuit. Chinese Patent Applications CN 202211596095.9 and CN 202110361366.1 respectively disclose methods for determination by detecting the variation characteristics of third harmonic current in neutral line current and three-phase secondary current of lines A, B and C, and the proportion of second harmonic components. However, when a large number of new energy sources are connected or a system fault occurs, the harmonic characteristics in the system will change, easily leading to misjudgment. Moreover, high-order harmonic current collection has high requirements for sampling frequency and precision.

The second is the out-of-zone fault analysis method. In case of a ground fault in a power system, the waveform characteristics of protection elements outside the fault range after startup are analyzed in the fault power grid area to determine whether the neutral line of the current circuit is open. Chinese Patent Application CN 202111317427.0 discloses a method for determining neutral line open circuit by comparing and analyzing the waveform characteristics of two sets of protection devices when a fault occurs outside the line protection zone. This method has high determination accuracy, but is limited to detection only when a power system fault occurs and cannot provide early warning before the system fault, which may cause accidents accompanied by out-of-zone or in-zone faults, resulting in limited effect of neutral line open circuit monitoring.

The third is the signal injection method. An external signal is added to the secondary current circuit to determine the neutral line open circuit. Chinese Patent Application CN 200710062678.2 discloses a method for detecting current injection type neutral line open circuit, which injects a weak electric signal into the operating secondary current circuit and effectively detects the neutral line open circuit of the system by monitoring the injected signal. This method has high determination accuracy and sensitivity, but causes great interference to the operation of relay protection devices, possibly leading to incorrect actions of relay protection devices and potential safety hazards.

In summary, to realize monitoring of loose connection or open circuit of neutral lines in current secondary circuits in practical application, the following problems need to be solved.

Firstly, real-time, sensitive and accurate determination of loose connection or open circuit of neutral lines in current secondary circuits. During normal system operation, the current on the neutral line of the current circuit is very small compared with the three-phase load current of phase A, B and C, so the sensitivity and accuracy of determining loose connection or open circuit are essential and important.

Secondly, low current data collection requirements. During normal system operation, the neutral line current of each bay is small. Remote data transmission is realized on the premise of meeting precision requirements, while high-frequency sampling may increase difficulties in data transmission and storage, and cause installation difficulties due to improved functional requirements of monitoring components.

Thirdly, avoiding influences of system harmonics and fault transients and improving anti-interference performance. When a large number of new energy sources are connected or a system fault occurs, harmonic interference and transient components will be generated in the system, which may greatly interfere with the determination of loose connection or open circuit and cause frequent false alarm information in practical application.

Fourthly, realizing comprehensive monitoring and precise positioning. There are a large number of secondary current windings in the power grid. After neutral line open circuit occurs in different windings, it is crucial to accurately and quickly identify and rectify the open circuit of the corresponding substation, bay and winding.

Lastly, identifying operating state of primary and secondary equipment. The neutral line current is closely related to the operating state of equipment. Direct open circuit determination without considering the state of primary and secondary equipment may cause false early warnings of loose connection or open circuit.

It is difficult to determine the unstable state of the secondary current circuit, where the neutral line of the secondary current is not completely loose or open, and the secondary wire connection may cycle between disconnection and recovery with uncertain duration, possibly remaining normal for a long time.

### SUMMARY

In view of the above existing problems, the present application is provided.

Therefore, the present application provides an online monitoring method for operating state of a secondary current circuit neutral line, which can solve the problems of weak electric field intensity of the measured object and difficulty in high-precision measurement in related art.

To solve the above technical problems, the present application provides the following technical solution: an online monitoring method for operating state of a secondary current circuit neutral line, including:
collecting neutral line current, by a high-precision sensor, and processing the collected neutral line current through a composite filtering algorithm to obtain fundamental components of secondary currents of each of neutral lines in a substation free from influences of harmonics and transients, and uploading the fundamental components to a protection information master station;
retrieving information from an original configuration connected to the protection information master station to acquire three-phase secondary current circuit information of each bay in the substation, summarizing secondary current information of all monitoring ranges, and performing grouping and classification marking by substation, bay and winding; and
conducting operation and analysis through collected information, automatically identifying and confirming an operating state of a line first, and calculating a linearity of outlier deviation and continuous dynamic trend deviation degree of each winding in each bay according to the operating state.

In an embodiment, the step of retrieving information from the original configuration connected to the protection information master station includes:
installing open-type high-precision micro current sensors on neutral lines of secondary current of each winding to collect neutral line current information, and processing the current information through an information collection system and uploading processed information to the protection information master station, where a sampling precision of the neutral line current is at milliampere level;
the information collection system refers to a hardware and software system installed at a station end, configured for communicating with accessed neutral line current online monitoring modules and comprehensive data modules, and completing collection and monitoring of relevant current information, data processing and remote transmission;
the information collection system includes a collection unit for collecting neutral line current data of secondary current circuits in a terminal box, a server for data transmission, a protocol converter and a wireless receiving and convergence unit, and is configured to upload data sampled by the collection unit to the protection information master station through a production management area network;
the production management area network is a partition interconnected with remote relevant production management areas through an enterprise integrated service data network, with a security level lower than a security level of a non-control zone in each security zone;
the protection information master station refers to an information platform deployed at a dispatching organization to perform remote relevant services for secondary equipment at the station end, analyzing and processing neutral line current data of secondary current circuits uploaded by the information collection system, determining whether loose connection or open circuit exists in the neutral lines of the secondary current, and issuing abnormal alarm information; and
the information collection system is configured to filter DC components and harmonic components in the secondary current circuits through the composite filtering algorithm to obtain fundamental component data of neutral line current for comprehensive analysis and calculation.

In an embodiment, the comprehensive analysis and calculation includes the following formula:

$$\{ \begin{matrix}{I}_{nc} = {\int }_{0}^{T} \vert {{I}^{\&}}_{A} \vert cos ( ω t + θ ) cos ( ω t ) dt = \frac{2}{N} {\sum }_{i = 1}^{N} {I}_{Ai} \cdot cos ( i \frac{2 π}{N} ) \\ {I}_{nj} = {\int }_{0}^{T} \vert {{I}^{\&}}_{A} \vert cos ( ω t + θ ) sin ( ω t ) dt = \frac{2}{N} {\sum }_{i = 1}^{N} {I}_{A i} \cdot sin ( i \frac{2 π}{N} )\end{matrix}$$

where I_{nc} is a real part of an effective value of fundamental current converted to a complex plane, Iₙⱼ is an imaginary part of the effective value, [symbol] is a maximum amplitude of current, ω is an angular frequency of alternating current, T is a period of alternating current, N is a number of sampling points in one period, i is an i-th sampling, and I_{Ai} is an i-th sampling value; and
a fundamental effective amplitude of neutral line current of each bay is calculated:

$${I}_{o} = \frac{\sqrt{2}}{T} \sqrt{{I}_{n c}^{2} + {I}_{nj}^{2}} .$$

In an embodiment, the step of retrieving information from the original configuration connected to the protection information master station includes:
directly collecting three-phase current data of phase A, B and C of a relay protection device and a fault filter device of each bay through an originally configured protection information sub-station in the substation, transmitting to the protection information master station for unified aggregation and processing with neutral line current data, and marking and confirming three-phase currents Ia₁, Ib₁, I_{c1} of phase A, B and C and neutral line current I₀₁ of a first winding, three-phase currents Ia₂, Ib₂, I_{c2} of phase A, B and C and neutral line current I₀₂ of a second winding, up to three-phase currents Ia₁, Ib₁, I_{c1} of phase A, B and C and neutral line current I₀₁ of an i-th winding corresponding to a certain bay of a certain substation;
where within the global monitoring range, once loose connection or open circuit occurs in a neutral line of any winding, a faulty winding is accurately positioned and reported immediately after comprehensive analysis and calculation.

In an embodiment, the step of conducting operation and analysis through the collected information includes:
analyzing and calculating current information marked and processed by the protection information master station, calculating an average value

$${I}_{a} = \frac{1}{{N}_{1}} {\sum }_{0}^{{N}_{1}} {I}_{a effective} ( t )$$

of an effective value of fundamental component of three-phase current within one minute, where I_{a effective} (t) is the effective value of phase A current of a relevant protection device collected by the master station at time t, N1 is a number of sampling points of telemetering information collected by the master station in a current period, and calculation methods of I_{b} and I_{c} are same as Iₐ; and determining an operating state of a line a primary equipment of a main transformer according to the following formula:
when the line is in a loaded operation state, Iₐ>0.01In|I_{b}>0.01In|I_{c}>0.01In; and
when the line is in an unoperated state or no-load state, Iₐ≤0.01In&I_{b}=0.01In&I_{c}=0.01In;
where In is a rated current of secondary current of the bay; and
when the line is in an unoperated state or no-load state, a zero drift sampling requirement of the relay protection device and the fault filter device is no more than 0.01In, and no determination on loose connection or open circuit of the neutral line in the secondary current circuit is conducted, with the neutral line deemed normal by default; and when the line is in a loaded operation state, a neutral line open circuit determination logic is activated.

In an embodiment, the step of conducting operation and analysis through the collected information further includes:
setting a composite outlier value

$${I}_{1 q} = \vert n \vert {I}_{0 i} \vert - \vert {\sum }_{i = 1}^{i = n} {I}_{0 i} \vert \vert$$

for each winding based on neutral line current sampling data I₀₁, I₀₂ . . . I₀ₙ through neutral line current data of different windings in a same bay, where n is a number of windings collected in the bay, so as to improve a discrimination of open-circuit windings;
calculating a standard deviation σ of neutral line current of each winding:

$$σ = \sqrt{\frac{{\sum }_{i = 1}^{i = n} {( \vert {I}_{0 i} \vert - \frac{\vert {\sum }_{i = 1}^{i = n} {I}_{0 i} \vert}{n} )}^{2}}{n - 1}} ;$$

calculating a correction coefficient F according to a maximum outlier deviation:

$$ε = \frac{4}{3 n \sqrt{n}} ;$$

and
calculating, by the protection information master station, the linearity of outlier deviation βi of neutral line current of each winding under a condition of neutral line open circuit in a branch circuit:

$${β}_{i} = \frac{4 \vert n \vert {I}_{0 i} \vert - \vert {\sum }_{i = 1}^{i = n} {I}_{0 i} \vert \vert}{3 n \sqrt{\frac{n \cdot {\sum }_{i = 1}^{i = n} {( \vert {I}_{0 i} \vert - \frac{\vert {\sum }_{i = 1}^{i = n} {I}_{0 i} \vert}{n} )}^{2}}{n - 1}}} ;$$

where I₀ᵢ is an effective value of sampling fundamental component of neutral line current of an i-th secondary winding, n is a number of neutral line currents of a bay connected to the protection information master station, and p is the linearity of outlier deviation of neutral line current of the i-th secondary winding; and
through statistical analysis and calculation, the βi value of non-open-circuit phases is less than 0.9, and the βi value of open-circuit phases is greater than 0.9 with a certain margin;
taking the reliability coefficient Krel as 1.1, a critical value K of the linearity of outlier deviation is set to 1; when the linearity of outlier deviation βi<1, the neutral line of the winding is preliminarily determined to operate normally by the protection information master station; and when βi≥1, loose connection or open circuit are preliminarily determined to exist in the neutral line of the winding by the protection information master station, and logical determination is continued.

In an embodiment, the linearity of outlier deviation and continuous dynamic trend deviation degree includes:
real-time collecting milliampere-level current data of the neutral line on a same winding, and performing the following operation based on neutral line current sampling data I₀₁, I₀₂ . . . I₀ₙ at different times:
conducting real-time precise monitoring of milliampere-level current of the neutral line in a secondary alternating current (AC) circuit, collecting and recording data, calculating and recording sampling average values Iₘₙ and I_{dn} of neutral line current in the current 200 milliseconds and 1 minute, sampling average values Iₘ₁ and I_{dn1} of a first one statistical cycle, sampling average values Iₘₙ₂ and I_{dn2} of a first two statistical cycle, . . . sampling average values Iₘₙ₁₀ and I_{dn10} of a first ten statistical cycle respectively to form a historical database; when the neutral line current is greater than twice a minimum precision current, comparing current average values of each statistical cycle in the database to obtain an instantaneous dynamic trend deviation degree and continuous dynamic trend deviation degree; this criterion responds abruptly in case of open circuit and stops responding after the neutral line open circuit exceeds the statistical cycle, so the protection information master station does not determine loose connection or open circuit of the neutral line solely by this criterion, but takes it as an auxiliary criterion for logical determination, with the formula as follows:

$$\{ \begin{matrix}{ρ}_{mni} = \frac{\vert {I}_{mn} - {I}_{m n i} \vert}{\vert {I}_{m n i} \vert} \times 100 \% ; \\ {ρ}_{dni} = \frac{\vert {I}_{dn} - {I}_{dni} \vert}{\vert {I}_{dni} \vert} \times 100 \%\end{matrix} ,$$

where ρₘₙᵢ is the instantaneous dynamic trend deviation degree of neutral line current in n-th winding compared with i-th previous statistical cycle, and ρ_{dni} is the continuous dynamic trend deviation degree of the neutral line current in the n-th winding compared with the i-th previous statistical cycle; Iₘₙᵢ or I_{dni} is required to be greater than twice the minimum precision current, and the calculation is exited in response to that all comparison cycles fail to meet the requirement.

Another object of the present application is to provide an online monitoring system for operating state of a secondary current circuit neutral line, which can solve the unsolvable problems in the prior art by implementing the online monitoring method for operating state of a secondary current circuit neutral line.

In an embodiment, the system includes: a high-precision micro current sensor configured to collect neutral line current data of a current circuit;
an information collection system configured to transmit neutral line current data to a protection information master station;
a protection information master station configured to process data in instructions or system programs;
a comprehensive analysis module configured to analyze and determine open circuit conditions and issue early warnings; and
an early warning module configured to issue early warnings for determined abnormal conditions.

A computer device, including a memory and a processor, where the memory stores a computer program, and the processor executes the computer program to implement the steps of the online monitoring method for operating state of the secondary current circuit neutral line.

A computer-readable storage medium storing a computer program, where the computer program is executed by a processor to implement the steps of the online monitoring method for operating state of a secondary current circuit neutral line.

The method of the present application is based on neutral line current data collection, and adopts high-precision micro current sensors to access neutral lines in terminal boxes of each bay at the substation side in a non-contact manner. On the premise of ensuring precision, additional signal intrusion into the protection secondary current circuit is avoided, greatly improving the safety of operating secondary equipment.

The present application first retrieves the original three-phase current data of phase A, B and C of each bay from the protection information master station to determine the operating state of the operating bay, avoiding misjudgment of secondary current circuit open circuit of overhauled or no-load lines, and then further analyzes and determines lines in loaded operation. High-sensitivity linearity of outlier deviation algorithm is adopted to horizontally compare deviations of each winding through neutral line current information collected by homologous high-precision sensors, and windings with large linearity of outlier deviation are calculated and screened out. The vertical comparison of the continuous dynamic trend deviation degree algorithm of the winding is performed to realize double confirmation on the premise of ensuring sufficient sensitivity, and the accuracy of determining loose connection or open circuit of the neutral line is guaranteed simultaneously.

Meanwhile, the sensitive induction characteristic of instantaneous dynamic trend deviation degree is applied to sense and determine the unstable connection state of the neutral line, solving the problem that the intermittent neutral line in the secondary current circuit is concealed and difficult to detect. The neutral line current data collected by the present application is sampled and processed through a comprehensive filtering algorithm, and only the fundamental component of the current is required for analysis and calculation, realizing low current data collection and processing requirements for the monitoring module and data processing module of the information collection system.

Moreover, steady-state fundamental components are adopted for analysis, avoiding harmonic interference generated during large-scale access of new energy sources or fault transients in the system, and further ensuring the accuracy of determining loose connection or open circuit of the neutral line.

The present application transmits data to the protection information master station through the information sub-station at the station end, conducts comprehensive processing and analysis at the protection information master station, performs overall scheduling, realizes centralized monitoring of all secondary current neutral lines within the entire scheduling range, and performs grouping and classification marking on each winding, thus realizing comprehensive monitoring of the entire system and quickly and accurately positioning and issuing abnormal early warnings for a specific winding.

### BRIEF DESCRIPTION OF THE DRAWINGS

In order to illustrate the technical solutions in the embodiments of the present application more clearly, the following briefly introduces the accompanying drawings required for the description of the embodiments. Obviously, the drawings in the following description are only part of embodiments of the present application. For those skilled in the art, other drawings can also be obtained according to the structures shown in these drawings without any creative effort.

FIG. 1 is a schematic flow chart of an online monitoring method for operating state of a secondary current circuit neutral line according to an embodiment of the present application.

FIG. 2 is a schematic flow chart of an online monitoring system for operating state of a secondary current circuit neutral line according to an embodiment of the present application.

### DETAILED DESCRIPTION OF THE EMBODIMENTS

To make the above objectives, features and advantages of the present application more obvious and understandable, the specific embodiments of the present application will be described in detail below with reference to the accompanying drawings. Obviously, the described embodiments are part of the embodiments of the present application, not all of them. All other embodiments obtained by those skilled in the art without creative efforts based on the embodiments of the present application shall fall within the scope of the present application.

In the following description, numerous specific details are set forth to facilitate a thorough understanding of the present application, but the present application may be practiced otherwise than as described herein, and those skilled in the art may make similar generalizations without departing from the connotation of the present application, so the present application is not limited by the specific embodiments disclosed below.

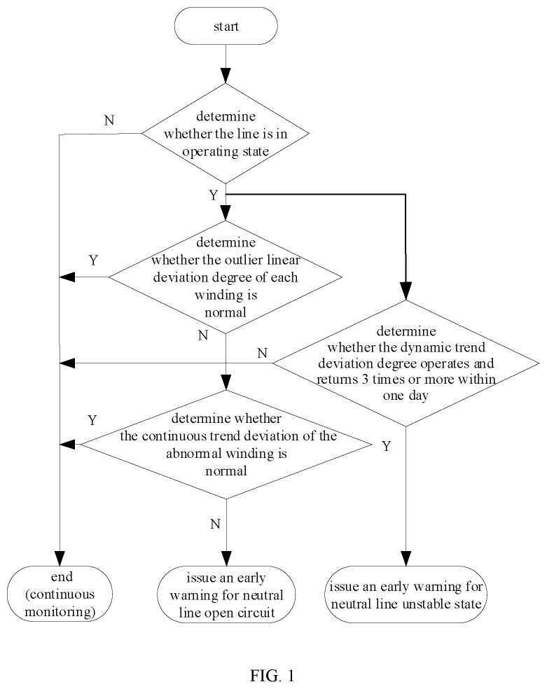

Referring to FIG. 1, an embodiment of the present application provides an online monitoring method for operating state of a secondary current circuit neutral line, including:

S1: collecting, by a high-precision sensor, and processing through a composite filtering algorithm to obtain fundamental components of secondary currents of each of neutral lines in a substation free from influences of harmonics and transients, and uploading the fundamental components to a protection information master station.

The step of retrieving information from the original configuration connected to the protection information master station includes: installing open-type high-precision micro current sensors on neutral lines of secondary current of each winding to collect neutral line current information, where the sampling precision of neutral line current is at milliampere level, and the neutral line current information is processed by the information collection system and is uploaded to the protection information master station.

The information collection system refers to a hardware and software system installed at a station end, configured for communicating with accessed neutral line current online monitoring modules and comprehensive data modules, and completing collection and monitoring of relevant current information, data processing and remote transmission. The information collection system includes a collection unit for collecting neutral line current data of secondary current circuits in a terminal box, a server for data transmission, a protocol converter and a wireless receiving and convergence unit, and uploads data sampled by the collection unit to the protection information master station through a production management area network, that is, a partition interconnected with remote relevant production management areas through an enterprise integrated service data network, with a security level lower than that of a non-control zone in each security zone.

The protection information master station refers to an information platform deployed at a dispatching organization to perform remote relevant services for secondary equipment at the station end, analyzing and processing neutral line current data of secondary current circuits uploaded by the information collection system, determining whether loose connection or open circuit exists in the neutral line of the current circuit, and issuing abnormal alarm information.

The information collection system filters direct current (DC) components and harmonic components in the secondary current circuits through the composite filtering algorithm to obtain fundamental component data of neutral line current for comprehensive analysis and calculation.

The comprehensive analysis and calculation includes the following formula:

$$\{ \begin{matrix}{I}_{nc} = {\int }_{0}^{T} \vert {{I}^{\&}}_{A} \vert cos ( ω t + θ ) cos ( ω t ) dt = \frac{2}{N} {\sum }_{i = 1}^{N} {I}_{Ai} \cdot cos ( i \frac{2 π}{N} ) \\ {I}_{nj} = {\int }_{0}^{T} \vert {{I}^{\&}}_{A} \vert cos ( ω t + θ ) sin ( ω t ) dt = \frac{2}{N} {\sum }_{i = 1}^{N} {I}_{A i} \cdot sin ( i \frac{2 π}{N} )\end{matrix}$$

where I_{nc} an Iₙⱼ are the real part an imaginary part of the effective value of fundamental current converted to a complex plane, [symbol] is the maximum amplitude of current, ω is the angular frequency of alternating current, T is the period of alternating current, N is the number of sampling points in one period, i is the i-th sampling, and I_{Ai} is the i-th sampling value.

The fundamental effective amplitude of neutral line current of each bay is calculated:

$${I}_{o} = \frac{\sqrt{2}}{T} \sqrt{{I}_{n c}^{2} + {I}_{nj}^{2}} .$$

S2: retrieving information from an original configuration connected to the protection information master station to acquire three-phase secondary current circuit information of each bay in the substation, summarizing secondary current information of all monitoring ranges, and performing grouping and classification marking by substation, bay and winding.

The retrieving step includes: directly collecting three-phase current data of phase A, B and C of a relay protection device and a fault filter device of each bay through an originally configured protection information sub-station in the substation, transmitting the data to the protection information master station for unified aggregation and processing with neutral line current data, and marking and confirming three-phase currents Iₐ₁, I_{b1}, I_{c1} of phase A, B and C and neutral line current I₀₁ of the first winding, three-phase currents Iₐ₂, I_{b2}, I_{c2} of phase A, B and C and neutral line current I₀₂ of the second winding, up to three-phase currents Iₐ₁, I_{b1}, I_{c1} of phase A, B and C and neutral line current I₀₁ of the i-th winding corresponding to a certain bay of a certain substation. Within the global monitoring range, once loose connection or open circuit occurs in the neutral line of any winding, the faulty winding is accurately positioned and reported immediately after comprehensive analysis and calculation.

S3: conducting operation and analysis through collected information, automatically identifying and confirming an operating state of a line first, and calculating a linearity of outlier deviation and continuous dynamic trend deviation degree of each winding in each bay according to the operating state.

The step of performing operation and analysis with the collected information includes: analyzing and calculating current information marked and processed by the protection information master station, calculating the average value

$${I}_{a} = \frac{1}{{N}_{1}} {\sum }_{0}^{{N}_{1}} {I}_{a} {}_{effective} ( t )$$

of the effective value of fundamental component of three-phase current within 1 minute, where I_{a effective} (t) is the effective value of phase A current of the relevant protection device collected by the master station at time t, N1 is the number of sampling points of telemetering information collected by the master station in the current period, and the calculation methods of phase I_{b} and I_{c} are the same as that of phase Iₐ; then determining the operating state of the line and primary equipment of the main transformer according to the following formula:
when the line is in a loaded operation state, Iₐ>0.01In|I_{b}>0.01In|I_{c}>0.01In; and
when the line is in an unoperated state or no-load state, Iₐ≤0.01In&I_{b}=0.01In&I_{c}=0.01In;
where In is the rated current of secondary current of the bay.

When the line is in an unoperated state or no-load state, the zero drift sampling requirement of the relay protection device and fault filter device is no more than 0.01In, and no determination on loose connection or open circuit of the neutral line in the secondary current circuit is conducted, with the neutral line deemed normal by default. When the line is in a loaded operation state, the neutral line open circuit determination logic is activated.

The step of performing operation and analysis with the collected information further includes: through the neutral line current data of different windings in the same bay, based on neutral line current sampling data I₀₁, I₀₂ . . . I₀ₙ, setting a composite outlier value I_{lq} for each winding to improve the discrimination of open-circuit windings:

$${I}_{1 q} = \vert n \vert {I}_{0 i} \vert - \vert {\sum }_{i = 1}^{i = n} {I}_{0 i} \vert \vert ;$$

calculating the standard deviation σ of neutral line current of each winding:

$$σ = \sqrt{\frac{{\sum }_{i = 1}^{i = n} {( \vert {I}_{0 i} \vert - \frac{\vert {Σ}_{i = 1}^{i = n} {I}_{0 i} \vert}{n} )}^{2}}{n - 1}} .$$

Under the rated current of a protection winding of a current transformer, the current amplitude error is no more than 3%, the phase error is no more than 1°, and the composite error of an open-type high-precision micro current sensor installed on a neutral line is no more than 5%. According to each voltage level configured with ground protection in the power grid, the number of protection windings used on site ranges from three to six. Considering that the effective sampling of protection is not less than twice the minimum precision current (i.e., greater than 2 mA), and the correction coefficient ε is calculated according to the maximum outlier deviation:

$$ε = \frac{4}{3 n \sqrt{n}} .$$

Finally, the protection information master station calculates the linearity of outlier deviation βi of neutral line current of each winding under the condition of neutral line open circuit in the branch circuit:

$${β}_{i} = \frac{4 \vert n \vert {I}_{0 i} \vert - \vert {\sum }_{i = 1}^{i = n} {I}_{0 i} \vert \vert}{3 n \sqrt{\frac{n {\sum }_{i = 1}^{i = n} {( \vert {I}_{0 i} \vert - \frac{\vert {Σ}_{i = 1}^{i = n} {I}_{0 i} \vert}{n} )}^{2}}{n - 1}}} ,$$

where I₀ᵢ is the effective value of sampling fundamental component of neutral line current of the i-th secondary winding, n is the number of neutral line currents of the bay connected to the protection information master station, and βᵢ is the linearity of outlier deviation of neutral line current of the i-th secondary winding.

Through statistical analysis and calculation, the βᵢ values of non-open-circuit phases are less than 0.9, and the open-circuit phases are greater than 0.9 with a certain margin. Taking the reliability coefficient Krel as 1.1, and the critical value K of linearity of outlier deviation is set to 1. When the linearity of outlier deviation βᵢ<1, the protection information master station preliminarily determines that the neutral line of the winding operates normally. When βᵢ≥1, the protection information master station preliminarily determines that loose connection or open circuit exists in the neutral line of the winding, and proceeds to logical determination.

The linearity of outlier deviation and continuous dynamic trend deviation degree includes: by acquiring milliampere-level current data of the neutral line on the same winding in real time, and performing the following operations based on the neutral line current sampling data I₀₁, I₀₂, . . . , I₀ₙ at different time points:

conducting real-time precise monitoring of milliampere-level current of the neutral line in the secondary alternating current (AC) circuit, collecting and recording data, calculating and recording the sampling average values Iₘₙ and I_{dn} of neutral line current in the current 200 milliseconds and 1 minute, the sampling average values Iₘ₁ and I_{dn}i of the previous statistical cycle, Iₘₙ₂ and I_{dn2} of the second previous statistical cycle . . . Iₘₙ₁₀ and I_{dn10} of the tenth previous statistical cycle with 200 milliseconds and 1 minute as collection cycles respectively to form a historical database. When the neutral line current is greater than twice the minimum precision current, comparing the current average values of each statistical cycle in the database to obtain the instantaneous dynamic trend deviation degree and the continuous dynamic trend deviation degree. Since this criterion responds abruptly upon an open circuit and ceases to respond once the neutral line open circuit persists beyond the statistical cycle, the protection information master station shall not determine loose connection or open circuit of the neutral line solely based on this criterion. As an auxiliary criterion for logical determination, the formula is as follows:

$$\{ \begin{matrix}{ρ}_{mni} = \frac{\vert {I}_{mn} - {I}_{mni} \vert}{\vert {I}_{mni} \vert} \times 100 \% ; \\ {ρ}_{dni} = \frac{\vert {I}_{dn} - {I}_{dni} \vert}{\vert {I}_{dni} \vert} \times 100 \% ;\end{matrix}$$

where ρₘₙᵢ and ρ_{dni} are the instantaneous dynamic trend deviation degree and the continuous dynamic trend deviation degree of the neutral line current of the n-th winding compared with those of the i-th previous statistical cycle respectively. Iₘₙᵢ or I_{dni} is required to be greater than twice the minimum precision current, and the calculation is exited if all comparison cycles fail to meet the requirement. According to the current power grid operation, the daily minimum load rate is about 0.6-0.8 under no special operation mode, and the power load changes slightly within 10 minutes. When the neutral line is open, the neutral line current drops to the sampling zero drift value instantaneously. Taking the reliability coefficient Krel′ greater than 1.2, the critical value of dynamic trend deviation degree is set to 40%.

Comparing the neutral point current data of a winding in the previous ten cycles to obtain a continuous dynamic trend deviation degree data set ρ_{dn1}, ρ_{dn2} . . . , ρ_{dn10}. When the dynamic trend deviation degree of neutral line current of any winding meets ρ_{dni}<40%, the winding is auxiliary determined to have normal neutral line operation. When any ρ_{dni}>40% in the data set, the winding is auxiliary determined to have loose connection or open circuit in the neutral line.

When the winding is preliminarily determined to have loose connection or open circuit in the neutral line and meets the continuous dynamic trend deviation degree criterion, an early warning of loose connection or open circuit of the neutral line in the secondary current circuit is issued immediately.

Comparing the neutral point current data of a winding in the previous ten cycles to obtain an instantaneous dynamic trend deviation degree data set ρₘₙ₁, ρₙₘ₂ . . . , ρₘₙ₁₀. When ρₘₙ₁≥40% of the winding of the bay, the neutral line is determined to have instantaneous abnormality. When the winding has three or more instantaneous abnormality actions and resets within one day, the winding is determined to be in an unstable neutral line state, and an early warning of neutral line abnormality in the secondary current circuit is issued immediately.

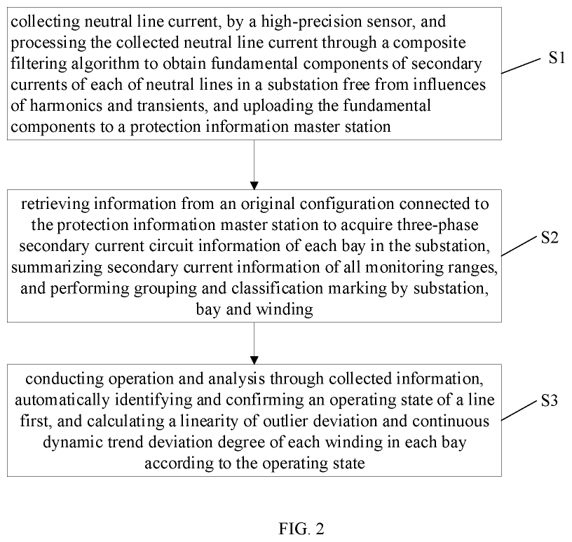

Referring to FIG. 2, an embodiment of the present application provides a non-contact micro intelligent sensing optimization system for potential in secondary DC circuits, including:
a high-precision micro current sensor configured to collect neutral line current data of a current circuit; an information collection system configured to transmit neutral line current data to a protection information master station; a protection information master station configured to process data in instructions or system programs; a comprehensive analysis module configured to analyze and determine open circuit conditions and issue early warnings; and an early warning module configured to issue early warnings for determined abnormal conditions.

It should be noted that the above embodiments are only used to illustrate the technical solutions of the present application rather than limit them. Although the present application has been described in detail with reference to preferred embodiments, those skilled in the art should understand that the technical solutions of the present application can be modified or equivalently replaced without departing from the spirit and scope of the technical solutions of the present application, and all such modifications or replacements shall fall within the scope of the claims of the present application.

An embodiment of the present application differs from the above embodiments in that:
if the functions are implemented in the form of software functional units and sold or used as independent products, they can be stored in a computer-readable storage medium. Based on this understanding, the technical solutions of the present application essentially or the part contributing to the prior art or part of the technical solutions can be embodied in the form of software products. The computer software products are stored in a storage medium and include several instructions to enable a computer device, which can be a personal computer, a server, or a network device, to execute all or part of the steps of the methods described in the embodiments of the present application. The storage media include: U disk, mobile hard disk, read-only memory (ROM), random access memory (RAM), magnetic disk or optical disk and other media that can store program codes.

It should be noted that the above embodiments are only used to illustrate the technical solutions of the present application rather than limit them. Although the present application has been described in detail with reference to preferred embodiments, those skilled in the art should understand that the technical solutions of the present application can be modified or equivalently replaced without departing from the spirit and scope of the technical solutions of the present application, and all such modifications or replacements shall fall within the scope of the claims of the present application.

Those skilled in the art understand that the embodiments of the present application can be provided as methods, systems or computer program products. Therefore, the present application can adopt the form of a complete hardware embodiment, a complete software embodiment or an embodiment combining software and hardware. Moreover, the present application can adopt the form of a computer program product implemented on one or more computer-usable storage media (including but not limited to disk storage, CD-ROM, optical storage, etc.) containing computer-usable program codes. The solutions in the embodiments of the present application can be implemented in various computer languages, such as object-oriented programming language Java and interpreted scripting language JavaScript.

The present application is described with reference to flowcharts and/or block diagrams of methods, devices (systems) and computer program products according to the embodiments of the present application. It should be understood that each flow and/or block in the flowcharts and/or block diagrams, and combinations of flows and/or blocks in the flowcharts and/or block diagrams can be realized by computer program instructions. These computer program instructions can be provided to a processor of a general-purpose computer, a special-purpose computer, an embedded processor or other programmable data processing devices to produce a machine, so that the instructions executed by the processor of the computer or other programmable data processing devices generate devices for realizing the functions specified in one or more flows in the flowcharts and/or one or more blocks in the block diagrams.

These computer program instructions can also be stored in a computer-readable memory that can guide a computer or other programmable data processing devices to work in a specific way, so that the instructions stored in the computer-readable memory produce a manufacture including an instruction device, and the instruction device realizes the functions specified in one or more flows in the flowcharts and/or one or more blocks in the block diagrams.

These computer program instructions can also be loaded onto a computer or other programmable data processing devices, so that a series of operation steps are executed on the computer or other programmable devices to produce computer-implemented processing, so that the instructions executed on the computer or other programmable devices provide steps for realizing the functions specified in one or more flows in the flowcharts and/or one or more blocks in the block diagrams.

Although the embodiments of the present application have been described, those skilled in the art can make additional changes and modifications to these embodiments once they know the basic inventive concept. Therefore, the appended claims are intended to be interpreted as including the preferred embodiments and all changes and modifications falling within the scope of the present application.

Obviously, those skilled in the art can make various changes and modifications to the present application without departing from the spirit and scope of the present application. Thus, if these modifications and variations of the present application fall within the scope of the claims of the present application and their equivalents, the present application is also intended to include these modifications and variations.

The test steps are as follows.

Five random time data within 10 minutes after the neutral line of a winding of a 220 kV operating line in a substation is open are selected, and the sampling values of neutral line winding current of all windings in the bay are recorded to form data table 1.

TABLE 1
neutral point current data of each winding
during neutral point open circuit

| | | time | time | time | time | time |
|---|---|---|---|---|---|---|
| | | point 1 | point 2 | point 3 | point 4 | point 5 |
| | | (mA) | (mA) | (mA) | (mA) | (mA) |
| neutral | winding 1 | 5 | 5 | 5 | 5 | 4 |
| line | winding 2 | 4 | 5 | 5 | 5 | 5 |
| current | winding 3 | 5 | 5 | 4 | 4 | 4 |
| of the | winding 4 | 0 | 1 | 0 | 0 | 1 |
| operating | winding 5 | 4 | 4 | 5 | 5 | 4 |
| line | | | | | | |

(1) The linearity of outlier deviation βᵢ of each winding at each time is calculated to obtain the linearity data of outlier deviation.

TABLE 2
linearity data of outlier deviation of each
winding during neutral point open circuit

| | | time | time | time | time | time |
|---|---|---|---|---|---|---|
| | | point 1 | point 2 | point 3 | point 4 | point 5 |
| linearity | winding 1 | 0.402 | 0.344 | 0.330 | 0.330 | 0.157 |
| of outlier | winding 2 | 0.112 | 0.344 | 0.330 | 0.330 | 0.550 |
| deviation | winding 3 | 0.402 | 0.344 | 0.055 | 0.055 | 0.157 |
| of the | winding 4 | 1.043 | 1.042 | 1.045 | 1.045 | 1.023 |
| operating | winding 5 | 0.112 | 0 | 0.330 | 0.330 | 0.157 |
| line | | | | | | |

(2) The three-phase current and neutral line current data of the operating line with neutral line open circuit and the no-load line in a substation 10 minutes before and after the open circuit is selected, and the measured values are recorded to form data table 3.

TABLE 3
test data of winding current 10 minutes
before and after neutral line open circuit

| operating line | | phase A | phase B | phase C | neutral line |
|---|---|---|---|---|---|
| (open-circuit | | current | current | current | current |
| winding data) | | (mA) | (mA) | (mA) | (mA) |
| | 10 minutes before | 721 | 730 | 730 | 5.1 |
| | 9 minutes before | 725 | 728 | 721 | 4.4 |
| | 8 minutes before | 724 | 730 | 728 | 5.0 |
| | 7 minutes before | 730 | 727 | 720 | 5.1 |
| | 6 minutes before | 729 | 730 | 727 | 4.2 |
| | 5 minutes before | 728 | 728 | 724 | 4.5 |
| | 4 minutes before | 727 | 721 | 727 | 4.4 |
| | 3 minutes before | 720 | 723 | 720 | 4.9 |
| | 2 minutes before | 721 | 729 | 727 | 5.0 |
| | 1 minute before | 723 | 730 | 720 | 5.0 |
| | time 0 of open- | 723 | 730 | 720 | 1.7 |
| | circuit | | | | |
| | 1 minute after | 724 | 724 | 728 | 0.1 |
| | 2 minutes after | 728 | 722 | 725 | 0.1 |
| | 3 minutes after | 724 | 727 | 727 | 0.0 |
| | 4 minutes after | 728 | 723 | 727 | 0.0 |
| | 5 minutes after | 727 | 721 | 721 | 0.0 |
| | 6 minutes after | 725 | 730 | 723 | 0.1 |
| | 7 minutes after | 726 | 722 | 728 | 0.1 |
| | 8 minutes after | 722 | 725 | 727 | 0.1 |
| | 9 minutes after | 729 | 730 | 726 | 0.0 |
| | 10 minutes after | 721 | 721 | 722 | 0.1 |

The line operating state is calculated according to the three-phase current of phase A, B and C, with In=1A, meeting the requirements:

$${I}_{a} > 0.01 In \vert {I}_{b} > 0.01 In \vert {I}_{c} > 0.01 In ;$$

The line is in operation, and the continuous dynamic trend deviation degree of the winding at each time is calculated to obtain data table 4 of continuous dynamic trend deviation degree.

TABLE 4
continuous dynamic trend deviation degree of the winding during neutral line open circuit

| | | | open- | 1st | 2nd | 3rd | 4th | 5th | 6th | 7th | 8th | 9th | 10th | subse- |
|---|---|---|---|---|---|---|---|---|---|---|---|---|---|---|
| | | first | circuit | subse- | subse- | subse- | subse- | subse- | subse- | subse- | subse- | subse- | subse- | quent |
| | | 1-10 | time | quent | quent | quent | quent | quent | quent | quent | quent | quent | quent | time |
| | comparison | cycles | point | cycle | cycle | cycle | cycle | cycle | cycle | cycle | cycle | cycle | cycle | points |
| continuous | previous | <30% | 67% | >80% | >80% | >80% | >80% | >80% | >80% | >80% | >80% | >80% | >80% | / |
| dynamic | 10 cycles | | | | | | | | | | | | | |
| trend | previous | <30% | 61% | >80% | >80% | >80% | >80% | >80% | >80% | >80% | >80% | >80% | / | / |
| deviation | 9 cycles | | | | | | | | | | | | | |
| degree | previous | <30% | 66% | >80% | >80% | >80% | >80% | >80% | >80% | >80% | >80% | / | / | / |
| of the | 8 cycles | | | | | | | | | | | | | |
| open- | previous | <30% | 67% | >80% | >80% | >80% | >80% | >80% | >80% | >80% | / | / | / | / |
| circuit | 7 cycles | | | | | | | | | | | | | |
| winding | previous | <30% | 60% | >80% | >80% | >80% | >80% | >80% | >80% | / | / | / | / | / |
| in the | 6 cycles | | | | | | | | | | | | | |
| operating | previous | <30% | 62% | >80% | >80% | >80% | >80% | >80% | / | / | / | / | / | / |
| line | 5 cycles | | | | | | | | | | | | | |
| | previous | <30% | 61% | >80% | >80% | >80% | >80% | / | / | / | / | / | / | / |
| | 4 cycles | | | | | | | | | | | | | |
| | previous | <30% | 65% | >80% | >80% | >80% | / | / | / | / | / | / | / | / |
| | 3 cycles | | | | | | | | | | | | | |
| | previous | <30% | 66% | >80% | >80% | / | / | / | / | / | / | / | / | / |
| | 2 cycles | | | | | | | | | | | | | |
| | previous | <30% | 66% | >80% | / | / | / | / | / | / | / | / | / | / |
| | 1 cycle | | | | | | | | | | | | | |

(4) The three-phase current and neutral line current data of the operating line with neutral line open circuit and the no-load line in a substation 2 seconds before and after the open circuit is selected, and the measured values are recorded to form data table 5.

TABLE 5
test data of winding current 2 seconds
before and after neutral line open circuit

| operating line | | neutral |
|---|---|---|
| (open circuit | | line current |
| winding data) | | (mA) |
| | 10 × 0.2 s before | 4.0 |
| | 9 × 0.2 s before | 4.0 |
| | 8 × 0.2 s before | 4.3 |
| | 7 × 0.2 s before | 4.1 |
| | 6 × 0.2 s before | 4.2 |
| | 5 × 0.2 s before | 4.4 |
| | 4 × 0.2 s before | 4.3 |
| | 3 × 0.2 s before | 4.1 |
| | 2 × 0.2 s before | 4.0 |
| | 1 × 0.2 s before | 4.0 |
| | time 0 of | 1.4 |
| | open circuit | |
| | 1 × 0.2 s after | 0.1 |
| | 2 × 0.2 s after | 0.1 |
| | 3 × 0.2 s after | 0.0 |
| | 4 × 0.2 s after | 0.0 |
| | 5 × 0.2 s after | 0.0 |
| | 6 × 0.2 s after | 0.1 |
| | 7 × 0.2 s after | 0.1 |
| | 8 × 0.2 s after | 0.1 |
| | 9 × 0.2s after | 0.0 |
| | 10 × 0.2 s after | 0.1 |

The dynamic trend deviation degree of the winding at each time is calculated to obtain data table 6 of dynamic trend deviation degree.

TABLE 6
dynamic trend deviation degree of the winding during neutral line open circuit

| | | | open- | 1st | 2nd | 3rd | 4th | 5th | 6th | 7th | 8th | 9th | 10th | subse- |
|---|---|---|---|---|---|---|---|---|---|---|---|---|---|---|
| | | first | circuit | subse- | subse- | subse- | subse- | subse- | subse- | subse- | subse- | subse- | subse- | quent |
| | | 1-10 | time | quent | quent | quent | quent | quent | quent | quent | quent | quent | quent | time |
| | comparison | cycles | point | cycle | cycle | cycle | cycle | cycle | cycle | cycle | cycle | cycle | cycle | points |
| dynamic | previous | 30% | 65% | >80% | >80% | >80% | >80% | >80% | >80% | >80% | >80% | >80% | >80% | / |
| trend | 10 cycles | | | | | | | | | | | | | |
| deviation | previous | <30% | 65% | >80% | >80% | >80% | >80% | >80% | >80% | >80% | >80% | >80% | / | / |
| degree | 9 cycles | | | | | | | | | | | | | |
| of the | previous | <30% | 67% | >80% | >80% | >80% | >80% | >80% | >80% | >80% | >80% | / | / | / |
| open- | 8 cycles | | | | | | | | | | | | | |
| circuit | previous | <30% | 66% | >80% | >80% | >80% | >80% | >80% | >80% | >80% | / | / | / | / |
| winding | 7 cycles | | | | | | | | | | | | | |
| in the | previous | <30% | 67% | >80% | >80% | >80% | >80% | >80% | >80% | / | / | / | / | / |
| operating | 6 cycles | | | | | | | | | | | | | |
| line | previous | <30% | 68% | >80% | >80% | >80% | >80% | >80% | / | / | / | / | / | / |
| | 5 cycles | | | | | | | | | | | | | |
| | previous | <30% | 67% | >80% | >80% | >80% | >80% | / | / | / | / | / | / | / |
| | 4 cycles | | | | | | | | | | | | | |
| | previous | <30% | 66% | >80% | >80% | >80% | / | / | / | / | / | / | / | / |
| | 3 cycles | | | | | | | | | | | | | |
| | previous | <30% | 65% | >80% | >80% | / | / | / | / | / | / | / | / | / |
| | 2 cycles | | | | | | | | | | | | | |
| | previous | <30% | 65% | >80% | / | / | / | / | / | / | / | / | / | / |
| | 1 cycle | | | | | | | | | | | | | |

According to the test data and calculation results, the line is first determined whether it is in operation. The test results show that the line operates normally, and the protection master station system continuously determines the neutral point secondary current circuit.

After the neutral line of a protection winding of a 220 kV line in a substation is open, the linearity of outlier deviation of the winding in the bay is 04>1, and all other windings are less than 1, so the secondary current neutral line of the winding is preliminarily determined to be open.

Continuous trend deviation degree analysis is conducted after the neutral line is open. The average current calculated in the statistical cycle is 1.7 mA, and the continuous trend deviation degree compared with the previous 10 cycles is all greater than 40%, which reconfirms that the neutral line of the secondary circuit is open, and the protection information master station issues an early warning. In addition, the open circuit determination conditions are met in the subsequent 10 cycles. After 10 cycles, the current is less than twice the minimum precision current, so the determination logic is no longer activated.

If the protection neutral line is in an unstable state, the average current calculated in the statistical cycle is 1.4 mA, and the dynamic trend deviation degree compared with the previous 10 cycles is all greater than 40%. If the same winding has three or more determination conversion between satisfaction and dissatisfaction within one day, the protection information master station determines that the neutral line of the secondary circuit is in an unstable state and issues an early warning.

What is claimed is:

1. An online monitoring method for an operating state of a secondary current circuit neutral line, comprising:
collecting neutral line current, by a high-precision sensor, and processing the collected neutral line current through a composite filtering algorithm to obtain fundamental components of secondary currents of each of neutral lines in a substation free from influences of harmonics and transients, and uploading the fundamental components to a protection information master station;
retrieving information from an original configuration connected to the protection information master station to acquire three-phase secondary current circuit information of each bay in the substation, summarizing secondary current information of all monitoring ranges, and performing grouping and classification marking by substation, bay and winding; and
conducting operation and analysis through collected information, automatically identifying and confirming an operating state of a line first, and calculating a linearity of outlier deviation and continuous dynamic trend deviation degree of each winding in each bay according to the operating state.

2. The online monitoring method for the operating state of the secondary current circuit neutral line according to claim 1, wherein
the step of retrieving information from the original configuration connected to the protection information master station comprises: installing open-type high-precision micro current sensors on neutral lines of secondary current of each winding to collect neutral line current information, and processing the current information through an information collection system and uploading processed information to the protection information master station, wherein a sampling precision of the neutral line current is at milliampere level;
the information collection system is a hardware and software system installed at a station end, configured for communicating with accessed neutral line current online monitoring modules and comprehensive data modules, and completing collection and monitoring of relevant current information, data processing and remote transmission; the information collection system comprises a collection unit for collecting neutral line current data of secondary current circuits in a terminal box, a server for data transmission, a protocol converter, and a wireless receiving and convergence unit, and the information collection system is configured to upload data sampled by the collection unit to the protection information master station through a production management area network; wherein the production management area network is a partition interconnected with remote relevant production management areas through an enterprise integrated service data network, with a security level lower than a security level of a non-control zone in each security zone;
the protection information master station is an information platform deployed at a dispatching organization to perform remote relevant services for secondary equipment at the station end, analyzing and processing neutral line current data of secondary current circuits uploaded by the information collection system, determining whether loose connection or open circuit exists in the neutral lines of the secondary current, and issuing abnormal alarm information; and
the information collection system is configured to filter direct current (DC) components and harmonic components in the secondary current circuits through the composite filtering algorithm to obtain fundamental component data of neutral line current for comprehensive analysis and calculation.

3. The online monitoring method for the operating state of the secondary current circuit neutral line according to claim 2, wherein the comprehensive analysis and calculation comprises the following formula:
$$\{ \begin{matrix}{I}_{uc} = {\int }_{0}^{T} \vert {{I}^{\&}}_{A} \vert cos ( ω t + θ ) cos ( ω t ) dt = \frac{2}{N} {\sum }_{i = 1}^{N} {I}_{Ai} cos ( i \frac{2 π}{N} ) \\ {I}_{uj} = {\int }_{0}^{T} \vert {{I}^{\&}}_{A} \vert cos ( ω t + θ ) sin ( ω t ) dt = \frac{2}{N} {\sum }_{i = 1}^{N} {I}_{Ai} sin ( i \frac{2 π}{N} )\end{matrix} ;$$
wherein I_{nc} is a real part of an effective value of fundamental current converted to a complex plane, Iₙⱼ is an imaginary part of the effective value, [symbol] is a maximum amplitude of current, ω is an angular frequency of alternating current, T is a period of alternating current, N is a number of sampling points in one period, i is an i-th sampling, and I_{Ai} is an i-th sampling value; and
a fundamental effective amplitude of neutral line current of each bay is calculated:
$${I}_{0} = \frac{\sqrt{2}}{T} \sqrt{{I}_{n c}^{2} + {I}_{nj}^{2}} .$$

4. The online monitoring method for the operating state of the secondary current circuit neutral line according to claim 3, wherein the step of retrieving information from the original configuration connected to the protection information master station comprises:
directly collecting three-phase current data of phase A, B and C of a relay protection device and a fault filter device of each bay through an originally configured protection information sub-station in the substation, transmitting to the protection information master station for unified aggregation and processing with neutral line current data, and marking and confirming three-phase currents Iₐ₁, I_{b1}, I_{c1} of phase A, B and C and neutral line current I₀₁ of a first winding, three-phase currents Iₐ₂, I_{b2}, I_{c2} of phase A, B and C and neutral line current I₀₂ of a second winding, up to three-phase currents Iₐ₁, I_{b1}, I_{c1} of phase A, B and C and neutral line current I₀₁ of an i-th winding corresponding to a certain bay of a certain substation; and
wherein within a global monitoring range, once loose connection or open circuit occurs in a neutral line of any winding, a faulty winding is accurately positioned and reported immediately after comprehensive analysis and calculation.

5. The online monitoring method for the operating state of the secondary current circuit neutral line according to claim 4, wherein the step of conducting operation and analysis through the collected information comprises:
analyzing and calculating current information marked and processed by the protection information master station, calculating an average value
$${I}_{a} = \frac{1}{{N}_{1}} {\sum }_{0}^{{N}_{1}} {I}_{a} {}_{effective} ( t )$$
of an effective value of fundamental component of three-phase current within one minute, wherein I_{a effective} (t) is the effective value of phase A current of a relevant protection device collected by the master station at time t, N1 is a number of sampling points of telemetering information collected by the master station in a current period, and calculation methods of I_{b} and I_{c} are same as Iₐ; and determining an operating state of a line a primary equipment of a main transformer according to the following formula:
when the line is in a loaded operation state, Iₐ>0.01In|I_{b}>0.01In|I_{c}>0.01In; and
when the line is in an unoperated state or no-load state, Iₐ≤0.01In&I_{b}=0.01In&I_{c}=0.01In;
wherein In is a rated current of secondary current of the bay; and
when the line is in an unoperated state or no-load state, a zero drift sampling requirement of the relay protection device and the fault filter device is no more than 0.01In, and no determination on loose connection or open circuit of the neutral line in the secondary current circuit is conducted, with the neutral line deemed normal by default; and when the line is in a loaded operation state, a neutral line open circuit determination logic is activated.

6. The online monitoring method for the operating state of the secondary current circuit neutral line according to claim 5, wherein the step of conducting operation and analysis through the collected information further comprises:
setting a composite outlier value
$${I}_{1 q} = \vert n \vert {I}_{0 i} \vert - \vert {\sum }_{i = 1}^{i = n} {I}_{0 i} \vert \vert$$
for each winding based on neutral line current sampling data I₀₁, I₀₂, . . . I₀ₙ through neutral line current data of different windings in a same bay, wherein n is a number of windings collected in the bay, so as to improve a discrimination of open-circuit windings;
calculating a standard deviation σ of neutral line current of each winding:
$$σ = \sqrt{\frac{{\sum }_{i = 1}^{i = n} {( \vert {I}_{0 i} \vert - \frac{\vert {Σ}_{i = 1}^{i = n} {I}_{0 i} \vert}{n} )}^{2}}{n - 1}} ;$$
calculating a correction coefficient F according to a maximum outlier deviation:
$$ε = \frac{4}{3 n \sqrt{n}} ;$$
and
calculating, by the protection information master station, the linearity of outlier deviation βᵢ of neutral line current of each winding under a condition of neutral line open circuit in a branch circuit:
$${β}_{i} = \frac{4 \vert n \vert {I}_{0 i} \vert - \vert {\sum }_{i = 1}^{i = n} {I}_{0 i} \vert \vert}{3 n \sqrt{\frac{n {\sum }_{i = 1}^{i = n} {( \vert {I}_{0 i} \vert - \frac{\vert {Σ}_{i = 1}^{i = n} {I}_{0 i} \vert}{n} )}^{2}}{n - 1}}} ;$$
wherein I₀ᵢ is an effective value of sampling fundamental component of neutral line current of an i-th secondary winding, n is a number of neutral line currents of a bay connected to the protection information master station, and βᵢ is the linearity of outlier deviation of neutral line current of the i-th secondary winding; and
through statistical analysis and calculation, βᵢ of non-open-circuit phases is less than 0.9, and βᵢ of open-circuit phases is greater than 0.9 with a certain margin; taking the reliability coefficient Krel as 1.1, a critical value K of the linearity of outlier deviation is set to 1; when the linearity of outlier deviation βᵢ<1, the neutral line of the winding is preliminarily determined to operate normally by the protection information master station; and when βᵢ>1, loose connection or open circuit are preliminarily determined to exist in the neutral line of the winding by the protection information master station, and logical determination is continued.

7. The online monitoring method for the operating state of the secondary current circuit neutral line according to claim 6, wherein the linearity of outlier deviation and continuous dynamic trend deviation degree comprises:
real-time collecting milliampere-level current data of the neutral line on a same winding, and performing the following operation based on neutral line current sampling data I₀₁, I₀₂, . . . , I₀ₙ at different times:
conducting real-time precise monitoring of milliampere-level current of the neutral line in a secondary alternating current (AC) circuit, collecting and recording data, calculating and recording sampling average values Iₘₙ and I_{dn} of neutral line current in the current 200 milliseconds and 1 minute, sampling average values Iₘₙ₁ and I_{dn1} of a first one statistical cycle, sampling average values Iₘₙ₂ and I_{dn2} of a first two statistical cycle, . . . , sampling average values Iₘₙ₁₀ and I_{dn10} of a first ten statistical cycle respectively to form a historical database; a criterion being as follows: when the neutral line current is greater than twice a minimum precision current, comparing current average values of each statistical cycle in the database to obtain an instantaneous dynamic trend deviation degree and continuous dynamic trend deviation degree; wherein the criterion responds abruptly in case of open circuit and stops responding after the neutral line open circuit exceeds the statistical cycle, so the protection information master station does not determine loose connection or open circuit of the neutral line solely by the criterion, but takes the criterion as an auxiliary criterion for logical determination, with the formula as follows:
$$\{ \begin{matrix}{ρ}_{mni} = \frac{\vert {I}_{mn} - {I}_{mni} \vert}{\vert {I}_{mni} \vert} \times 100 \% ; \\ {ρ}_{dni} = \frac{\vert {I}_{dn} - {I}_{dni} \vert}{\vert {I}_{dni} \vert} \times 100 \% ;\end{matrix}$$
wherein ρₘₙᵢ is the instantaneous dynamic trend deviation degree of neutral line current in n-th winding compared with i-th previous statistical cycle, and ρ_{dni} is the continuous dynamic trend deviation degree of the neutral line current in the n-th winding compared with the i-th previous statistical cycle; Iₘₙᵢ or I_{dni} is required to be greater than twice the minimum precision current, and the calculation is exited in response to that all comparison cycles fail to meet the requirement.

8. A system adopting the online monitoring method for the operating state of the secondary current circuit neutral line according to claim 1, comprising:
a high-precision micro current sensor configured to collect neutral line current data of a current circuit;
an information collection system configured to transmit neutral line current data to a protection information master station;
a protection information master station configured to process data in instructions or system programs;
a comprehensive analysis module configured to analyze and determine open circuit conditions and issue early warnings; and
an early warning module configured to issue early warnings for determined abnormal conditions.

9. A computer device, comprising a memory and a processor, wherein the memory stores a computer program, and the processor executes the computer program to implement the steps of the method according to claim 1.

10. A non-transitory computer-readable storage medium, storing a computer program, wherein the computer program is executed by a processor to implement the steps of the method according to claim 1.
